(19) United States
(12) Patent Application Publication
(10) Pub. No.: US 2006/0157711 A1
(43) Pub. Date: Jul. 20, 2006

(54) Thin film transistor array panel

(75) Inventor: Jin-Kyu Kang, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/324,669

(22) Filed: Jan. 3, 2006

(30) Foreign Application Priority Data
Jan. 19, 2005 (KR) 10-2005-0005012
Jan. 20, 2005 (KR) 10-2005-0005304

(51) Int. Cl. H01L 29/04

(52) U.S. Cl. 257/72

(57) ABSTRACT

A thin film transistor (TFT) array display panel is provided, which includes: a substrate; a plurality of semiconductor islands formed on the substrate (including a plurality of transistor source, channel, and drain regions); a gate insulating layer covering the semiconductor islands; a plurality of gate lines (including gate electrodes overlapping the channel regions) formed on the gate insulating layer; a plurality of data lines connected to the source regions and formed on the gate insulating layer; and a plurality of pixel electrodes connected to the drain regions. the number or at grain boundaries of the portion of the semiconductor that is selected as the gate region is varied (different, unequal) among the semiconductors in the same column of the array which prevents visible stripes due to current leakage caused by protrusions. The position of each semiconductor island (e.g., relative to one of the data lines) is varied (e.g., randomly) among semiconductors in the same column of the array. Alternatively, the position of the gate electrode which defines the gate region of the semiconductor island is varied (e.g., randomly) among uniformly positioned semiconductors in the same column of the array.

### BACKGROUND OF THE INVENTION

1. Field of the Invention

The present invention relates to a thin film transistor array panel using polysilicon as a semiconductor.

2. Description of Related Art

A thin film transistor (TFT) array panel is used as the substrate of a data driver circuit configured to individually drive each pixel in a flat panel display composed of a plurality of pixels, such as a liquid crystal display (LCD) or an organic light emitting diode display (OLED.

A liquid crystal display (LCD) includes two panels (substrates) each provided with field-generating electrodes (such as pixel electrodes and a common electrode), with a liquid crystal (LC) layer interposed therebetween. The LCD displays images by applying voltages to the field-generating electrodes to generate an electric field across the LC layer, which controls the orientations of LC molecules in the LC layer to adjust polarization of incident light.

An organic light emitting diode display (OLED) is a self emissive display device, which displays images by exciting a light-emissive organic material to emit light. The OLED includes an anode (hole injection electrode), a cathode (electron injection electrode), and an organic light emission layer interposed therebetween. When the holes and the electrons are injected into the light emission layer, they are recombined and pair-annihilated which emits light.

Each pixel of the OLED includes two transistors (such as a driving transistor and a switching transistor). The current for light emission is supplied through the driving TFTs and the amount of the current driven through the driving TFTs is controlled by the data signals from the corresponding switching TFTs.

Generally, the TFT includes a semiconductor made of amorphous silicon or crystalline silicon. Amorphous silicon is widely used in a display having glasses whose melting point is low, since amorphous silicon film can be fabricated at a relatively low temperature.

However, the amorphous silicon film has low carrier mobility, which affects the current carrying capacity of the film. Thus amorphous silicon may be unsuitable for implementing high quality driving circuits of display panels. Meanwhile, polycrystalline silicon has prominent electric field effect mobility, good high-frequency operation, a low leakage current. This, in general, high quality driving circuits require the polycrystalline silicon.

The electrical characteristics of a thin film transistor (TFT) made of polycrystalline silicon is affected by the size and the uniformity of grain. Thus, the electric field effect mobility of the TFT increases with the increase of the size and the uniformity of grain. The method selected used to form the polycrystalline silicon film may increase the size and the uniformity of its grain.

Excimer laser annealing (ELA) and chamber annealing are typical methods for producing polycrystalline silicon films. Recently, sequential lateral solidification (SLS) process which causes lateral growth of silicon crystalline has been proposed.

The SLS technique utilizes the phenomenon that the silicon grains grow laterally to the boundary of a liquid region and a solid region. In the SLS process, the sizes of the grains can have predetermined widths by controlling the irradiation range and the energy of a laser beam (e.g., using an optical system and a mask selectively interrupting a passing (scanning) laser beam.

After the sequential lateral solidification (SLS), protrusions of protuberances are formed on the surface of the polysilicon layer along the grain boundaries by grain that grow to each other. These protrusions can prevent the flow of the current, and this affect can result in a degradation of the characteristics of the TFTs, thereby causing visible defects in the display (such as horizontal stripe or vertical stripe).

### SUMMARY OF THE INVENTION

It is a feature of the present invention to provide a thin film transistor (TFT) array panel with uniform display quality without regard to the influence of the protrusions at grain boundaries on the surface of the polysilicon layer.

A thin film transistor (TFT) array panel is provided, which includes: a substrate; a plurality of semiconductors formed on the substrate and including a plurality of source and drain regions, and a plurality of channel regions; a gate insulating layer covering the semiconductors; a plurality of gate lines including a gate electrodes overlapping the channel regions and formed on the gate insulating layer; a plurality of data lines connected to the source regions and formed on the gate insulating layer; and a plurality of pixel electrodes connected to the drain regions, wherein the semiconductors are apart from the gate lines or the data lines with various distances.

The distances between the data lines and the gate electrodes may be uniform.

The semiconductors may further include a plurality of lightly doped regions disposed between the source and the drain regions and the channel regions, and the semiconductors further include a plurality of protrusions. The number of the protrusions formed on the lightly doped regions is various.

The semiconductors may further include a plurality of protrusions, and the number of the protrusions formed on the channel regions is various.

The protrusions may be disposed with uniform interval.

The thin film transistor array panel may further include a blocking layer formed between the substrate and the semiconductors.

The thin film transistor array panel may further include a passivation layer formed between the pixel electrode and the gate and the data lines.

The thin film transistor array panel may further include an interlayer insulating layer formed between the gate lines and the data lines, and a plurality of drain electrodes connecting the pixel electrode to the drain regions.

The thin film transistor array panel may further include a partition formed on the pixel electrode, and a plurality of light emitting members formed on the pixel electrodes and disposed in the openings defined by the partition.

The thin film transistor array panel may further include a plurality of storage electrode lines separated from the gate lines and formed on the substrate.

A thin film transistor array panel is provided, which includes: a substrate; a plurality of semiconductors formed on the substrate and including a plurality of source and drain regions, and a plurality of channel regions; a gate insulating layer covering the semiconductors; a plurality of gate lines including a gate electrodes overlapping the channel regions and formed on the gate insulating layer; a plurality of data lines connected to the source regions and formed on the gate insulating layer; and a plurality of pixel electrodes connected to the drain regions, wherein the semiconductors are apart from the gate electrodes with various distances.

The distances between the data lines and the semiconductors may be uniform.

The semiconductors may further include a plurality of lightly doped regions disposed between the source and the drain regions and the channel regions.

The semiconductors may further include a plurality of protrusions, and the number of the protrusions formed on the lightly doped regions is various.

The semiconductors may further include a plurality of protrusions, and the number of the protrusions formed on the channel regions is various.

The protrusions may be disposed with uniform interval.

### BRIEF DESCRIPTION OF THE DRAWINGS

The present invention will become more apparent by describing embodiments thereof in detail with reference to the accompanying drawings,

Thin film array panel according to embodiments of the present invention now will be described more fully hereinafter with reference to the accompanying drawings, in which preferred embodiments of the invention are shown. This invention may, however, be embodied in many different forms and should not be construed as limited to the embodiments set forth herein. Like numerals refer to like elements throughout.

In the drawings, the thickness of layers and regions are exaggerated for clarity. Like numerals refer to like elements throughout. It will be understood that when an element such as a layer, region, or substrate is referred to as being “on” another element, it can be directly on the other element or intervening elements may also be present. By contrast, when an element is referred to as being “directly on” another element, there are no intervening elements present.

In the following drawings:

FIG. 1 is a layout view of the TFT array panel for an LCD according to an embodiment of the present invention;

FIG. 2 is a sectional view of the TFT array panel of FIG. 1 taken along the section lines II-II′-II″;

FIG. 3 is a layout view showing the central lines of a horizontal and a vertical axis for the semiconductor islands disposed in a plurality of pixel in the TFT array panel shown in FIGS. 1 and 2 according to an embodiment of the present invention;

FIG. 4 is a layout view showing the relative position between the protrusions and the lightly doped drain regions formed in the semiconductor islands disposed in a plurality of pixels in the TFT array panel shown in FIGS. 1 and 2;

FIG. 5 is a layout view showing the relative position between the protrusions, the gate electrodes and the channel regions formed in the semiconductor islands disposed in a plurality of pixel in the TFT array panel according to another embodiment of the present invention;

FIG. 6 is a layout view showing the relative position between the protrusions and the lightly doped drain regions formed in the semiconductor islands disposed in a plurality of pixels in the TFT array panel according to still another embodiment of the present invention;

FIG. 7 is a layout view of the TFT array panel for an OLED according to an embodiment of the present invention; and

FIGS. 8 and 9 are sectional views of the TFT array panel shown in FIG. 7 taken along the section lines VIII-VIII′ and IX-IX′, respectively.

### DETAILED DESCRIPTION OF EMBODIMENTS

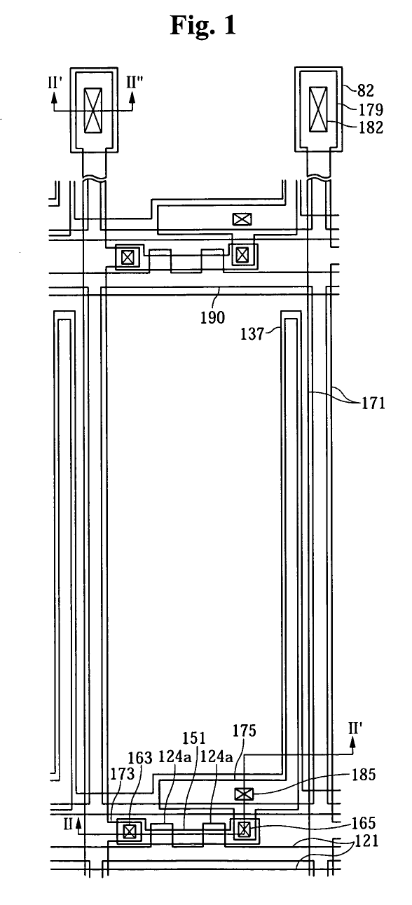

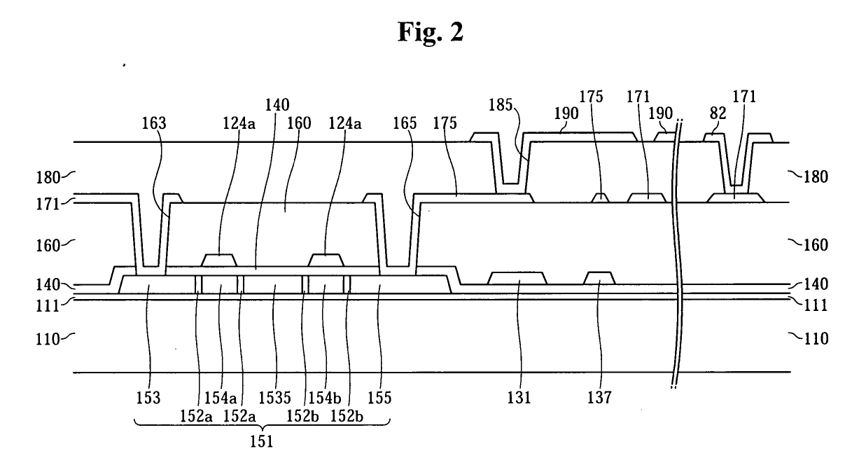

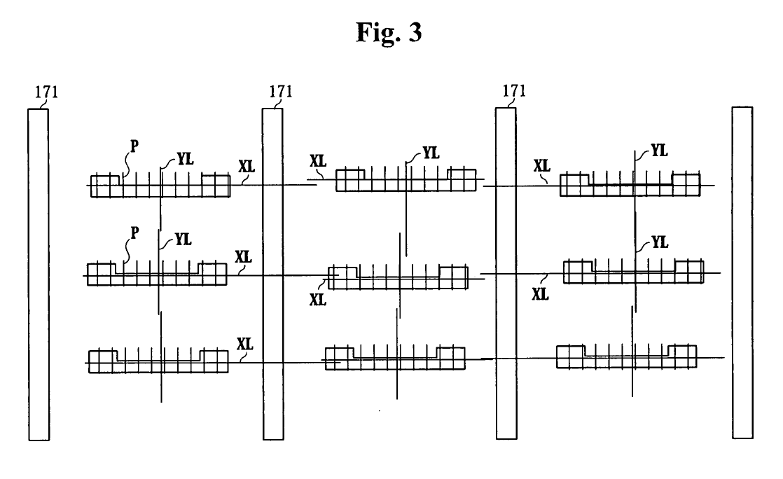

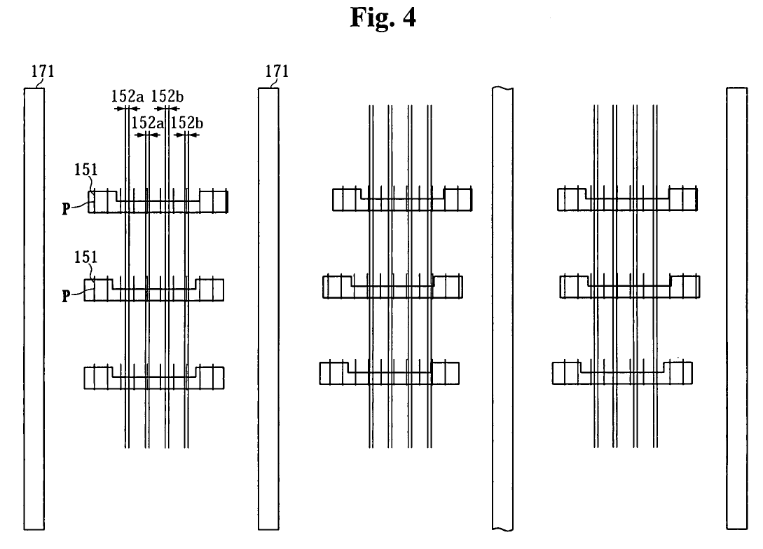

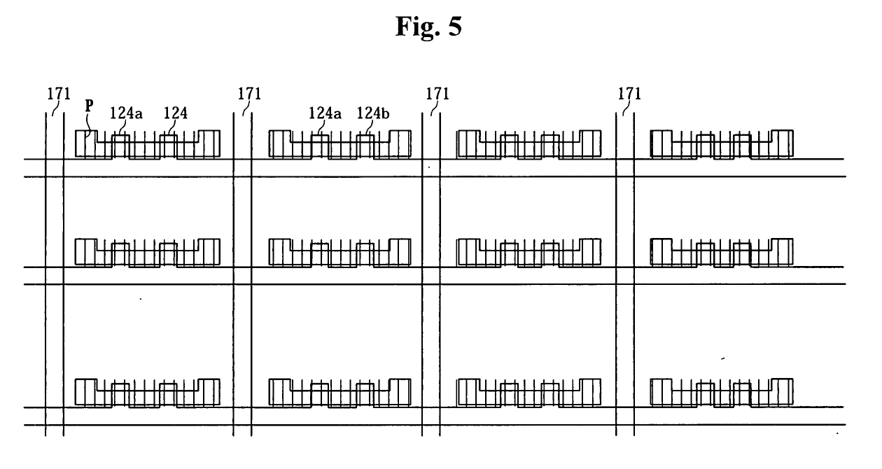

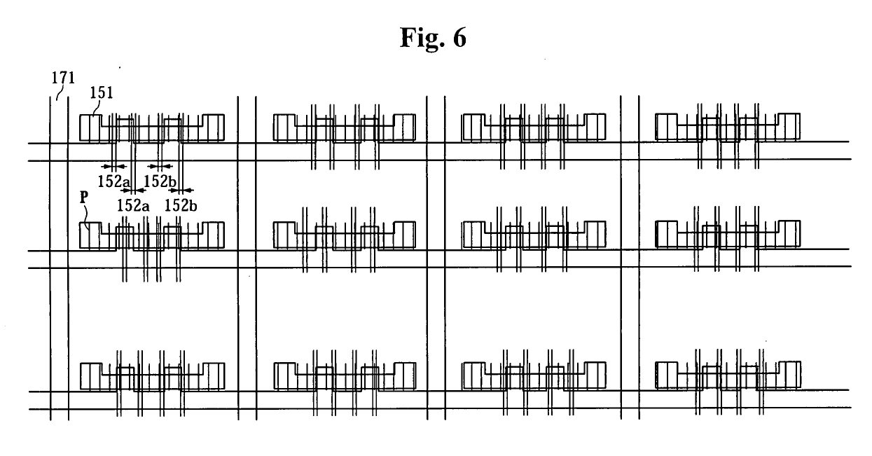

FIG. 1 is a layout view of the TFT array panel for an LCD according to an embodiment of the present invention, while FIG. 2 is a sectional view of the TFT array panel of FIG. 1 taken along the section lines II-II′ and II′-II″, FIG. 3 is a layout view showing the central lines of a horizontal and a vertical axis for the semiconductor islands disposed in a plurality of pixels in the TFT array panel of FIGS. 1 and 2 according to an embodiment of the present invention, FIG. 4 is a layout view showing the relative position between the protrusions and the lightly doped drain regions formed in the semiconductor islands disposed in a plurality of pixels in the TFT array panel of FIGS. 1 and 2 according to an embodiment of the present invention, FIG. 5 is a layout view showing the relative position between the protrusions, the gate electrodes and the channel regions formed in the semiconductor islands disposed in a plurality of pixels in the TFT array panel according to another embodiment of the present invention, and FIG. 6 is a layout view showing the relative position between the protrusions and the lightly doped drain regions formed in the semiconductor islands disposed in a plurality of pixels in the TFT array panel according to another embodiment of the present invention.

A blocking film 111, preferably made of silicon oxide (SiO₂) or silicon nitride (SiNx), is formed on an insulating substrate 110 such as transparent glass, quartz. or sapphire. The blocking film 111 may have a multi-layered structure.

A plurality of semiconductor islands 151, preferably made of polysilicon are formed on the blocking film 111. Each of the semiconductor islands 151 includes a plurality of extrinsic regions containing N-type (or P-type) conductive impurities (doping) and at least one intrinsic region containing less of the conductive impurities (doping), and both end portions of the semiconductor islands 151 have a width wider than other portions of the semiconductors for making connections with other layers. Examples of N-type conductive impurities are phosphorous (P) and arsenic (As), and examples of P-type conductive impurities are boron (B) and gallium (Ga).

With regard to the semiconductor island 151, the intrinsic regions include channel regions 154a and 154b, and the extrinsic regions include a plurality of heavily doped regions (used as transistor source and drain) 153, 155 and (an intermediate region) 1535 (separated from the channel region 154a and 154b by a plurality of lightly doped regions 152a and 152b). Here, the number of heavily doped regions 153, 155 and 1535 may vary, and the number of channel regions may vary depending on the number of heavily doped regions 153, 155 and 1535.

The lightly doped regions 152 (152a, 152b) have relatively small thicknesses and lengths compared with the heavily doped regions 153 and 155, and are disposed close to surfaces of the semiconductor islands 151. The lightly doped regions 152a and 152b are referred to as “lightly doped drain (LDD) regions”, and they prevent leakage current of TFTs. The LDD regions may be replaced with offset regions that contain substantially no impurities.

To form the plurality of semiconductor islands 151, an amorphous silicon layer is formed on substrate 110 and then crystallized by sequential lateral solidification (SLS), and has a plurality of protrusions P as shown in FIGS. 3 to 6 formed on the grain boundaries at uniform intervals. In this embodiment of the present invention, the central lines (XL, YL) of the plurality of semiconductor islands 151 are not aligned. That is to say, as shown in FIG. 3, the vertical central lines YL and the horizontal central lines XL of the neighboring semiconductor islands 151 are not aligned, and are randomly shifted in their array on the substrate 110. Furthermore, the plurality of the protrusions P disposed on the LDD regions 152a and 152b are randomly distributed, as shown in FIG. 4.

When the thin film transistors (TFT) are turned OFF, a leakage current is generated, and the amount of the leakage current depends upon the number of the protrusions P formed on the semiconductor islands 151. The protrusions P formed in the TFT channels and lightly doped regions affect the current flow of the TFT, and the leakage current is changed, thereby changing the characteristics of the TFTs.

Therefore, the relative positions of the semiconductor islands 151 within the plurality of corresponding pixels are varied (shifted) randomly in the embodiment according to the present invention to obtain the electrical and optical characteristics of the TFTs in each pixel, thereby yielding a thin film transistor array panel having uniform display quality.

A gate insulating layer 140 (FIG. 2) made of silicon oxide (SiO₂) or silicon nitride (SiNx) is formed with a thickness of hundreds of angstroms upon the semiconductor islands 151 and upon the blocking layer 111.

A plurality of gate conductors including a plurality of gate lines 121 (124a) and a plurality of storage electrode lines 131 are formed on the gate insulating layer 140. The variation of the distance between the gate lines 121 (124a) and the semiconductor islands 151 are random.

The gate lines 121 for transmitting gate signals extend substantially in a transverse direction and include a plurality of gate electrodes 124a protruding to overlapping the channel areas 154a and 154b of the semiconductor islands 151. Each gate line 121 may include an expanded end portion (not shown, but similar to a line end portion comprised of 82, 171, 182) having a large area for contact with another layer or an external driving circuit. The gate lines 121 may be directly connected to a gate driving circuit (not shown) configured to generate the gate signals, and which may be integrated on the substrate 110. The gate electrodes 124a may be expanded to overlap the LDD regions 152a and 152b.

The gate electrodes 124a are disposed at the uniform positions within each pixel, in contrast with the random variation of position of the semiconductor islands 151.

As shown in FIGS. 5 and 6, the positions of overlapping portions of the gate electrodes 124a and the semiconductor islands 151 are varied to yield the thin film transistor array panel having uniform display quality.

Thus, the position within each pixel of overlapping portions of the gate electrodes 124a and the semiconductor islands 151 are randomly varied. Accordingly, the number of the protrusions P of the semiconductors 151 overlapping the gate electrodes 124a is randomly varied. Furthermore, the number of the protrusions P formed on the channel regions 154a and 154b, and the LDD regions 152a and 152b, which are defined by the gate electrodes 124a, are randomly varied.

As shown in FIGS. 5 and 6, the positions of overlapping portions of the gate electrodes 124a and the semiconductor islands 151 are randomly varied to randomly vary the number of the protrusions P formed on (or in) the channel regions 154a and 154b, and the LDD regions 152a and 152b, which are defined by the (randomly distributed) gate electrodes 124a, thereby randomly generating the leakage current in each pixel.

Accordingly, the electric and optical characteristics of the TFTs in each pixel may be variously and randomly obtained, thereby yielding the thin film transistor array panel having uniform display quality. When the positions of the gate electrode 124a and 124b are randomly varied, as shown in FIGS. 5 and 6, the semiconductor islands 151 may be disposed in a uniform position within each the pixel regions (defined by the intersection of the gate lines 121 and the data lines 171).

The storage electrode lines 131 are supplied with a predetermined voltage such as a common voltage, and include a plurality of storage electrodes 137 extending to the neighboring gate lines 121, and are disposed between the two consecutive gate lines 121.

The conductors 121 and lines 131 are preferably made of a low resistivity material including an Al-containing metal such as Al and an Al alloy (e.g. Al—Nd), an Ag-containing metal such as Ag and an Ag alloy, a Cu-containing metal such as Cu and a Cu alloy, a Mo-containing metal such as Mo and a Mo alloy, Cr, Ti, and Ta. The gate conductors 121, and 124b and lines 131 may have a multi-layered structure including two films having different physical characteristics. One of the two films is preferably made of a low resistivity metal including an Al-containing metal, an Ag-containing metal, and a Cu-containing metal for reducing signal delay or voltage drop in the gate conductors 121 and 131. The other film is preferably made of a material such as Cr, Mo, a Mo alloy, Ta, or Ti, which has good physical, chemical, and electrical contact characteristics with other materials such as indium tin oxide (ITO) and indium zinc oxide (IZO). Good examples of the combination of the two films are a lower Cr film and an upper Al—Nd alloy film, and a lower Al film and an upper Mo film.

In addition, (as shown in FIG. 2) the lateral sides (edges) of the conductors 121 and lines 131 are inclined relative to a surface of the substrate 110 to enhance overlying adhesion characteristics.

An interlayer insulating layer 160 is formed on the gate conductors 121 and 131. The interlayer insulating layer 160 is preferably made of a photosensitive organic material having a good flatness characteristic, a low dielectric insulating material such as a-Si:C:O and a-Si:O:F formed by plasma enhanced chemical vapor deposition (PECVD), or an inorganic material such as silicon nitride and silicon oxide.

The interlayer insulating layer 160 has a plurality of contact holes 163 and 165 through it respectively exposing the source regions 153 and the drain regions 155.

A plurality of data conductors including a plurality of data lines 171 and a plurality of output electrodes 175 are formed on the interlayer insulating layer 160. As shown in FIGS. 3 and 4, the transverse distances between the data lines 171 and each of the semiconductors 151 are randomly varied in each pixel.

The data lines 171 are provided for transmitting data voltages and extend substantially in the longitudinal direction and cross (over) the gate lines 121. Each data line 171 includes a plurality of input electrodes 173 extending to electrically connect to the source regions 153 through the contact holes 163. Each data line 171 includes an expanded end portion having a large area for contact with another layer or an external driving circuit. The data lines 171 may be directly connected to a data driving circuit (not shown) for generating the gate signals, which may be integrated on the substrate 110. The storage electrodes 137 are disposed between the data lines 171 and adjacent thereto.

The output electrodes 175 are separated from the input electrodes 173 and are connected to the drain regions 155 through the contact holes 165, and overlap the storage electrode 137 to form a storage capacitor.

The data conductors 171 and 175 are preferably made of a refractory metal including Cr, Mo, Ti, Ta, or alloys thereof. They may have a multi-layered structure preferably including a low resistivity film and a good contact film. A good example of the multi-layered structure includes a Mo lower film, an Al middle film, and a Mo upper film as well as the above-described combinations of a Cr lower film and an Al—Nd upper film and an Al lower film and a Mo upper film.

Like the conductors 121 and 131, the conductors 171 and 175 have tapered lateral sides (edges) relative to a planar surface of the substrate 110.

A passivation layer 180 is formed on the conductors 171 and 175 and the interlayer insulating layer 160. The passivation layer 180 is also preferably made of a photosensitive organic material having a good flatness characteristic, an insulating material having low (4.0 or less) dielectric such as a-Si:C:O and a-Si:O:F formed by PECVD, or an inorganic material such as silicon nitride and silicon oxide.

The passivation layer 180 has a plurality of contact holes 185 and 182 through it respectively exposing the output electrodes 175 and end portions of the data lines 171. The passivation layer 180 and the interlayer insulating layer 160 may further have a plurality of contact holes (not shown) exposing end portions of the gate lines 121.

A plurality of pixel electrodes 190 and a plurality of contact assistants 82, (which are preferably made of at least one of a transparent conductor such as ITO or IZO and opaque reflective conductor such as Al or Ag), are formed on the passivation layer 180.

The pixel electrodes 190 are physically and electrically connected to the output electrodes 175 through the contact holes 185 such that the pixel electrodes 190 receive the data voltages from the drain regions 155 (of TFTs) via the output electrodes 175.

The contact assistants 82 are connected to the end portions of the data lines 171 through the contact holes 182. The contact assistants 82 protect the end portions 179 and improve the adhesion of the end portions 179 to external devices.

The pixel electrodes 190 supplied with the data voltages generate electric fields in cooperation with the common electrode (not shown) disposed on the upper panel (not shown), which determines the orientations of liquid crystal (LC) molecules in a liquid crystal layer (not shown).

As described above, the pixel voltage of the pixel electrode 190 due to the leakage current of the thin film transistor (TFT) is randomly varied such that the transmittance of the pixel is random. Accordingly, the thin film transistors having the different leakage current are randomly distributed such that the local average of the transmittance of the pixel is uniform as compared to where the thin film transistors all have the same leakage current. Therefore, a visible stripe due to leakage current is eliminated, thereby obtaining uniform display quality.

In the liquid display, a pixel electrode 190 and a common electrode form a liquid crystal capacitor, which stores applied voltages after turn-off of the TFT. An additional capacitor called a “storage capacitor,” which is connected in parallel to the liquid crystal capacitor, is provided for enhancing the voltage storing capacity. The storage capacitors are implemented by overlapping the pixel electrodes 190 with the storage electrodes 133 as well as the storage lines 131. The storage electrodes 133 may be omitted depending on the required amount of the capacitance.

The pixel electrodes 190 overlap the gate lines 121 and the data lines 171 to increase aperture ratio but that overlap it is optional.

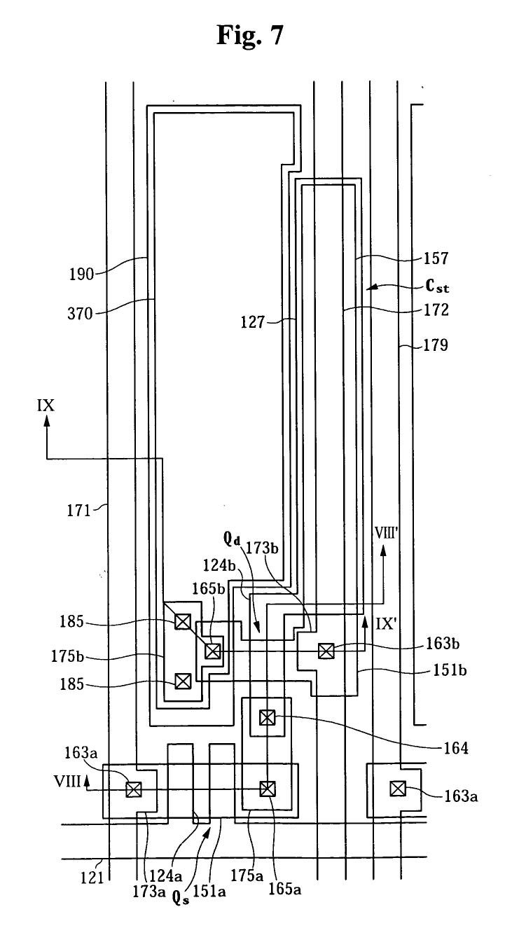

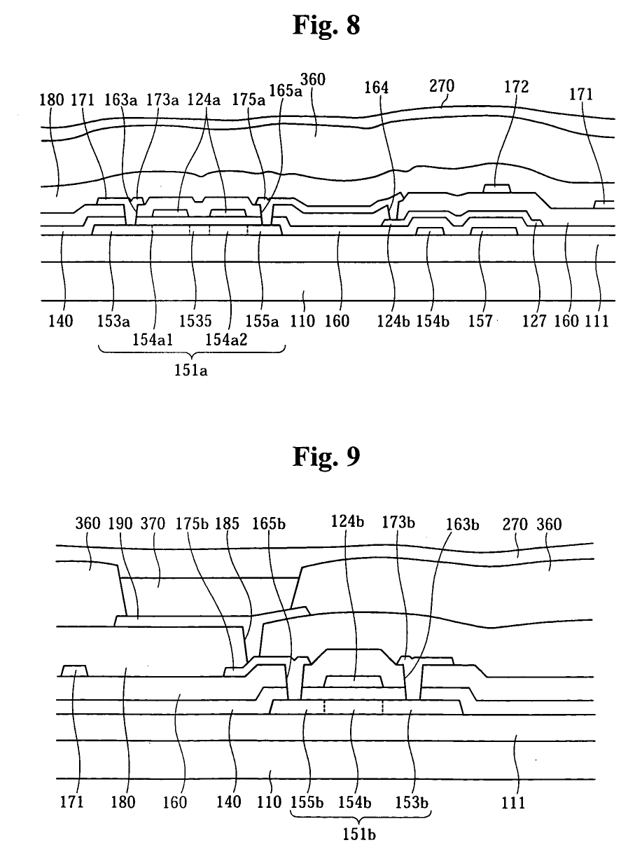

The above features may be adapted to other flat panel display devices such as an OLED as illustrated in FIGS. 7, 8 & 9.

FIG. 7 is a layout view of a TFT array panel for an OLED according to an embodiment of the present invention; and FIGS. 8 and 9 are sectional views of the TFT array panel of FIG. 7 taken along the section lines VIII-VIII′ and IX-IX′, respectively.

A blocking layer (film) 111 (FIGS. 8 & 9) preferably made of silicon oxide or silicon nitride is formed on an insulating substrate 110 preferably made of transparent glass. The blocking film 111 may have a dual-layered structure.

A plurality of semiconductor islands 151a and 151b preferably made of polysilicon are formed on the blocking film 111. Each of the semiconductor islands 151a and 151b includes a plurality of extrinsic regions containing N-type or P-type conductive impurity (dopants) and at least one intrinsic region containing less conductive impurity.

In a first semiconductor island 151a for providing a switching TFT, the extrinsic regions include a first source region 153a, an intermediate region 1535, and a first drain region 155a, that are separated from one another and are doped with an N-type impurity (dopant), and the intrinsic regions include such a pair of (first) channel regions 154a1 and 154a2 disposed between the extrinsic regions 153a, 1535 and 155a.

In a second semiconductor island 151b for providing a driving TFT, the extrinsic regions include a second source region 153b and a second drain region 155b, that are separated from one another and are doped with P-type conductive impurity, and the intrinsic region includes a channel region 154b disposed between the second source region 153b and the second drain region 155b. The extrinsic second source region 153b is extended longitudinally to form a storage (electrode) region 157.

The semiconductor islands 151 may further include lightly doped regions (not shown) disposed between the channel regions 154a1, 154a2 and 154b and the source and the drain regions 153a, 155a, 153b and 155b. The lightly doped regions may be substituted with offset regions that contain substantially no impurity.

Alternatively, the extrinsic regions 153a and 155a of the first semiconductor islands 151a are doped with P-type conductive impurity, while the extrinsic regions 153b and 155b of the second semiconductor islands 151b are doped with N-type conductive impurity, depending on driving conditions. The conductive impurity may include a P-type impurity such as boron (B) and gallium (Ga) and an N-type impurity such as phosphorous (P) and arsenic (As).

The semiconductor islands 151a and 151b may be made of amorphous silicon. In this case, there are no impurity regions and ohmic contacts for improving contact characteristics between semiconductor islands 151a and 151b. Metal layers may be formed directly on the semiconductor islands 151a and 151b.

Similarly as above described, to form the plurality of first and second semiconductor islands 151a and 151b, an amorphous layer is deposited and then crystallized by sequential lateral solidification (SLS), and the resulting semiconductor islands 151a and 151b have a plurality of protrusions formed at the grain boundaries at uniform distance intervals.

In this embodiment of the present invention, the central lines of the semiconductor islands 151a and 151b of the pixel adjacent thereto are not aligned. As shown in FIG. 3, the vertical central lines YL and the horizontal central lines XL of the neighboring semiconductor islands 151a and 151b are not aligned, and are positioned with random variation within pixels throughout the whole substrate 110.

The protrusions P formed in the channel and in the lightly doped regions affect the current flow of the thin film transistor (TFT), and the leakage current is affected, thereby changing the electric characteristics of the TFTs. Furthermore, the optical characteristics of the LCD is changed by the positions and the number of the protrusions in the semiconductor islands 151a and 151b.

A gate insulating layer 140 preferably made of silicon oxide or silicon nitride is formed on the semiconductor islands 151a and 151b and the blocking film 111.

A plurality of gate conductors including a plurality of gate lines 121 including a plurality of pairs of first gate electrodes 124a and a plurality of second gate electrodes 124b are formed on the gate insulating layer 140.

The gate lines 121 transmit gate signals and extend substantially in a transverse direction. Each pair of first gate electrodes 124a protrude upward (longitudinally) from the gate line 121 and they intersect (overlap) the first semiconductor islands 151a such that they overlap the pair of the first channel regions 154a1 and 154a2. Each gate line 121 may include an expanded end portion (not shown) having a large area for contact with another layer or an external driving circuit. The gate lines 121 may be directly connected to a gate driving circuit (not shown) that generates the gate signals, and which may be integrated on the substrate 110.

The second gate electrodes 124b are separated from the gate lines 121 and intersect (overlap) the second semiconductor islands 151b such that they overlap the second channel regions 154b. The second gate electrodes 124b are extended to form storage electrodes 127 overlapping the storage electrode regions 157 of the second semiconductor islands 151b, to form storage capacitors having capacitance Cst.

The distances between the gate lines 121 and semiconductor islands 151a and 151b are also varied randomly.

Furthermore, in an embodiment shown in FIGS. 5 and 6, the positions of the gate electrodes 124a and 124b overlapping and the semiconductors 151a and 151b are varied randomly, while the position of the semiconductors 151a and 151b are uniform in the each pixel.

If the number of the protrusions P in the portion of the semiconductor islands 151a and 151b overlapped by the gate electrodes 124a and 124b is randomly varied, the number of the protrusions P formed on the channel regions 154a1, 154a2 and 154b (which are defined by the gate electrodes 124a) are randomly varied.

As previously noted, the varied number of protrusions P formed in the channel and lightly doped regions affect the current flow of the thin film transistor, and the leakage current is changed, thereby changing the electric characteristics of the TFTs. Furthermore, the optical characteristics of the LCD is changed by the randomly varying positions and the number of the protrusions of the semiconductor islands 151a and 151b.

The gate conductors 121 and 124b are preferably made of low resistivity material including an Al-containing metal (such as Al and Al alloy (e.g. Al—Nd)), a Ag containing metal (such as Ag and Ag alloy), and a Cu containing metal (such as Cu and Cu alloy). The gate conductors 121 and 124b may have a multi-layered structure including two films having different physical characteristics. One of the two films is preferably made of low resistivity metal including Al containing metal, Ag containing metal, and Cu containing metal for reducing signal delay or voltage drop in the gate conductors 121 and 124b. The other film is preferably made of material such as Cr, Mo and Mo alloy, Ta or Ti, which has good physical, chemical, and electrical contact characteristics with other materials such as indium tin oxide (ITO) or indium zinc oxide (IZO). Good examples of the combination of the two films are a lower Cr film and an upper Al—Nd alloy film and a lower Al film and an upper Mo film.

In addition, the lateral sides (edges) of the gate conductors 121 and 124b are inclined relative to a surface of the substrate 110, and the inclination angle thereof ranges about 30-80 degrees.

An interlayer insulating film 160 (FIG. 8) is formed on the gate conductors 121 and 124b. The interlayer insulating layer 160 is preferably made of photosensitive organic material having a good flatness characteristic, an low dielectric (e.g., less than 4.0) insulating material such as a-Si:C:O and a-Si:O:F formed by plasma enhanced chemical vapor deposition (PECVD), or inorganic material such as silicon nitride and silicon oxide.

The interlayer insulating layer 160 has a plurality of contact holes 164 (FIGS. 7 and 8) through it exposing the second gate electrodes 124b. In addition, the interlayer insulating layer 160 and the gate insulating layer 140 have a plurality of contact holes 163a, 163b, 165a and 165b through it exposing the source regions 153a and 153b and the drain regions 155a and 155b, respectively.

A plurality of data conductors including a plurality of data lines 171, a plurality of driving voltage lines 172, and a plurality of first and second drain electrodes 175a and 175b are formed on the interlayer insulating film 160.

The data lines 171 for transmitting data signals extend substantially in the longitudinal direction and cross (over) the gate lines 121. Each data line 171 includes a plurality of first source electrodes 173a (connected to the first source regions 153a through the contact holes 163a). Each data line 171 may include an expanded end portion (not shown) having a large area for contact with another layer or an external driving circuit. The data lines 171 may be directly connected to a data driving circuit (not shown) for generating the gate signals, which may be integrated on the substrate 110.

The driving voltage lines 172 transmit driving voltages for the driving TFTs and extend substantially in the longitudinal direction and cross (over) the gate lines 121. Each voltage transmission line 172 includes a plurality of second source electrodes 173b extending from the driving voltage lines 172 to overlap and connected to the second source regions 153b (through the contact holes 163b). The driving voltage lines 172 overlap the storage electrode 127, and may be connected to each other.

The first drain electrodes 175a are separated from the data lines 171 and the driving voltage lines 172. The first drain electrodes 175a are connected to the first drain regions 155a (FIG. 8) through the contact holes 165, and to the second gate electrodes 124b (FIGS. 7, 8 &9) through the contact hole 164.

The second drain electrodes 175b (FIGS. 7 &9) are separated from the data lines 171 and from the driving voltage lines 172 and are connected to the second drain regions 155b (FIG. 9) (through the contact holes 165b).

The data conductors 171, 172, 175a and 175b are preferably made of refractory metal including Cr, Mo, Ti, Ta or alloys thereof. They may have a multi-layered structure preferably including a low resistivity film and a good contact film. Good example of the multi-layered structure are a double-layered structure including a lower Cr film and an upper Al (alloy) film, a double-layered structure of a lower Mo (alloy) film and an upper Al (alloy) film, and a triple-layered of a lower Mo film, an intermediate Al film, and an upper Mo film.

Like the gate conductors 121 and 124b, the conductors 171, 172, 175a and 175b have inclined edge profiles, and the inclination angles thereof range about 30-80 degrees.

A passivation layer 180 is formed on the conductors 171, 172, 175a and 175b. The passivation layer 180 is also preferably made of organic material, low dielectric insulating material, or inorganic material.

The passivation layer 180 has a plurality of contact holes 185 exposing the second drain electrodes 175b. The passivation layer 180 may further has a plurality of contact holes (not shown) exposing end portions of the data lines 171 and the passivation layer 180 and the interlayer insulating layer 160 may have a plurality of contact holes (not shown) exposing end portions of the gate lines 121 (not shown).

A plurality of pixel electrodes 190 are formed on the passivation layer 180.

The pixel electrodes 190 serve as anodes of light emitting elements and they are connected to the second drain electrodes 175b through the contact holes 185. The pixel electrodes 190 are preferably made of a transparent conductor such as ITO or IZO. However, the pixel electrode 190 may be made of an opaque reflective conductor such as Al, Ag, Ca, Ba and Mg.

A plurality of contact assistants or connecting members (not shown) may be also formed on the passivation layer 180 such that they are connected to the exposed end portions (not shown) of the gate lines 121, the data lines 171.

A partition 360 (FIGS. 8 & 9) for separating pixels of the OLED is formed on the passivation layer 180 and the pixel electrodes 190. The partition 360 surrounds the pixel electrodes 190 to define openings to be filled with organic light emitting material. The partition 360 is preferably made of organic or inorganic insulating material. The partition 360 is preferably made of a photosensitivity organic material including black resin. This partition 360 may play the role to a light blocking member and the manufacturing process may be thus simplified.

A plurality of light emitting members 370 are formed on the pixel electrodes 190 and disposed in the openings defined by the partition 360. The light emitting members 370 are preferably made of organic material emitting primary-color light such as red, green and blue light. The red, green and blue light emitting members 370 are periodically arranged (e.g., in patterns known to persons skilled in the art).

A common electrode 270 is formed on (e.g., directly on) the light emitting members and on the partition 360. The common electrode 270 is supplied with the common voltage Vcom.

The common electrode 270 is preferably made of reflective material such as Ba, Ca, Ma, Al, Ag, or their alloys, or transparent material such as ITO and IZO.

In the above-described OLED, a first semiconductor island 151a, a first gate electrode 124a (connected to the gate line 121), a first source electrode 153a (connected to the data line 171), and a first drain electrode 155a form a switching TFT Qs. In addition, a second semiconductor island 151b, a second gate electrode 124b (connected to the first drain electrode 155a), a second source electrode 153b (connected to the voltage transmission line 172), and a second drain electrode 155b (connected to a pixel electrode 190) form a driving TFT Qs. Furthermore, a storage region 157 (connected to the first drain region (electrode) 155a) and a storage electrode 127 (connected to a voltage transmission line 172 through a second source electrode 153b) form a storage capacitor Cst. The TFTs Qs and Qd shown in FIGS. 7-9 are referred to as “top gate TFTs” since the gate electrodes 124a and 124b are disposed on the semiconductors 151a and 151b.

The switching TFT Qs transmits data signals from the data line 171 in response to a gate signal from the gate line 121. The driving TFT Qd drives a current having a magnitude depending on the voltage difference between the second control electrode 124b and the second drain electrode 175b upon receipt of the data signals. The voltage difference between the gate electrode 124b and the second source electrode 173b is stored in the storage capacitor Cst and maintained after the switching TFT Qs turns off. The light emitting member 370 emits light having intensity depending on the current driven by the driving TFT Qd and the monochromatic primary color lights emitted from the light emitting members 370 are mixed in the human perception to display images.

As above described, the distances between the gate lines (or the data line), and the semiconductor islands (forming TFTs Qs and Qd), or the overlapping position of the gate electrode on the semiconductor islands, are varied randomly such that the display quality of thin film transistor array panel may be preserved. Accordingly, the electric and optical characteristics of the thin film transistor array panel are randomly varied among the pixels, according to the number of the protrusions formed on the channel regions and the doped regions, thereby yielding a display having uniform display quality.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A thin film transistor array panel comprising:
a substrate;
a plurality of semiconductors formed on the substrate and including a plurality of channel regions;
a gate insulating layer covering the channel regions of the semiconductors;
a plurality of gate lines connected to a plurality of gate electrodes that overlap the channel regions; and
a plurality of data lines;
wherein the corresponding semiconductors of two different pixels are situated in two different positions relative to their respective pixels.

2. The thin film transistor array panel of claim 1, wherein the semiconductors further include a plurality of protrusions.

3. The thin film transistor array panel of claim 1, wherein the distances between the data lines are uniform, and the distances between the gate lines are uniform.

4. The thin film transistor array panel of claim 1, wherein the corresponding semiconductors of two different pixels in the same column of the array are situated two different distances from the same data line.

5. The thin film transistor array panel of claim 1, wherein each of the semiconductors further includes a lightly doped region disposed between a source region and the channel region or between a drain region and the channel region.

6. The thin film transistor array panel of claim 5, wherein the semiconductors further include a plurality of protrusions, and the number of the protrusions formed on the lightly doped regions varies among the semiconductors of different pixels in the same column of the array.

7. The thin film transistor array panel of claim 1, wherein the semiconductors further include a plurality of protrusions, and the number of the protrusions formed on the channel regions varies among the semiconductors of different pixels in the same column of the array.

8. The thin film transistor array panel of claim 7, wherein the protrusions are disposed with a uniform distance interval.

9. The thin film transistor array panel of claim 1, further comprising:
a blocking layer formed between the substrate and the semiconductors.

10. The thin film transistor array panel of claim 1, further comprising:
a passivation layer formed between the pixel electrode and the gate lines and the data lines.

11. The thin film transistor array panel of claim 1, further comprising:
an interlayer insulating layer formed between the gate lines and the data lines, and
a plurality of drain electrodes connecting a plurality of pixel electrodes to a plurality of drain regions of the semiconductors.

12. The thin film transistor array panel of claim 1, further comprising:
a partition formed on the pixel electrode, and
a plurality of light emitting members formed on the pixel electrodes and disposed in the openings defined by the partition.

13. The thin film transistor array panel of claim 1, further comprising:
a plurality of storage electrode lines separated from the gate lines and formed on the substrate.

14. A thin film transistor array panel comprising:
a substrate;
a plurality of semiconductors formed on the substrate wherein each of the semiconductors includes a channel region;
a gate insulating layer covering the channel regions of the semiconductors;
a plurality of gate lines connected to gate electrodes that overlap the channel regions that are formed on the gate insulating layer; and
a plurality of data lines;
wherein the semiconductors are apart from the gate electrodes with various distances.

15. The thin film transistor array panel of claim 14, wherein the distances between the data lines and the semiconductors are uniform.

16. The thin film transistor array panel of claim 14, wherein each of the semiconductors further includes a plurality of lightly doped regions disposed between a source region of the semiconductor and the channel region and between a drain region of the semiconductor and the channel region.

17. The thin film transistor array panel of claim 16, wherein the semiconductors further include a plurality of protrusions, and the number of the protrusions formed on the lightly doped regions varies among different semiconductors in the same column of the array.

18. The thin film transistor array panel of claim 14, wherein the semiconductors further include a plurality of protrusions, and the number of the protrusions formed on the channel regions varies among different semiconductors in the same column of the array.

19. The thin film transistor array panel of claim 18, wherein the protrusions are disposed with uniform distance interval.

20. A display having a uniform array of pixels, comprising:
a substrate;
a plurality of thin-film semiconductor islands formed on the substrate, wherein each semiconductor island corresponds to one pixel of the array and includes one channel region;
a gate insulating layer covering the channel regions of the semiconductor islands;
a plurality of gate electrodes that overlap the channel regions and that are formed on the gate insulating layer;
wherein a first number j of protrusions are within the channel region of a first one of the plurality of semiconductor islands and a second number k of protrusions are within the channel region of a second one of the plurality of semiconductor islands, wherein j is not equal to k.

21. The display of claim 20, wherein j is equal to or greater than k+1.

22. The display of claim 21, wherein j is greater than k+1.

23. The display of claim 20, wherein the thin-film semiconductor islands formed on the substrate comprise a layer of polysilicon, and the protrusions are on the surface of the polysilicon layer.

24. The display of claim 20, wherein the first one of the plurality of semiconductor islands and the second one of the plurality of semiconductor islands are the same distance from a data line of the display.

25. The display of claim 20, wherein the first one of the plurality of semiconductor islands and the second one of the plurality of semiconductor islands in the same column of the pixel array are different distances from a data line of the display.

26. The display of claim 20, wherein a third one of the plurality of semiconductor islands in the same column of the pixel array is a different distance from the same data line of the display than the first and second ones of the plurality of semiconductor islands.

27. The display of claim 20, wherein the gate electrode that overlaps the channel region formed on the gate insulating layer of the first one of the plurality of semiconductor islands and the gate electrode that overlaps the channel region formed on the gate insulating layer of the second one of the plurality of semiconductor islands are the same distance from a data line of the display.

28. The display of claim 20, wherein the gate electrode that overlaps the channel region formed on the gate insulating layer of the first one of the plurality of semiconductor islands and the gate electrode that overlaps the channel region formed on the gate insulating layer of the second one of the plurality of semiconductor islands in the same column of the pixel array are different distances from a data line of the display.

29. The display of claim 20, wherein the gate electrode that overlaps the channel region formed on the gate insulating layer of a third one of the plurality of semiconductor islands in the same column of the pixel array and the gate electrodes that overlap the channel regions formed on the gate insulating layer of the first and second one of the plurality of semiconductor islands are different distances from a data line of the display.
